(19) United States
(12) Patent Application Publication
(10) Pub. No.: US 2005/0139390 A1
(43) Pub. Date: Jun. 30, 2005

(54) Printed circuit board and package having oblique vias

(76) Inventors: Han Kim, Daejeon (KR); Bong-Kyu Choi, Chungcheongbuk-do (KR); Dae-Cheol Seo, Daejeon (KR); Heung-Kyu Kim, Chungcheongbuk-do (KR); Sang-Kab Park, Chungcheongbuk-do (KR)

Correspondence Address: GOTTLIEB RACKMAN & REISMAN PC, 270 MADISON AVENUE, 8TH FLOOR, NEW YORK, NY, 100160601, US

(21) Appl. No.: 10/875,916

(22) Filed: Jun. 23, 2004

(30) Foreign Application Priority Data
Dec. 24, 2003 (KR) 2003-96784

(51) Int. Cl. H05K 7/06

(52) U.S. Cl. 174/262

(57) ABSTRACT

Disclosed herein is a via structure that minimizes high frequency loss. A PCB or an IC package of the present invention includes an insulation layer, a plurality of circuit layers, and one or more vias obliquely formed with respect to the circuit layers and constructed to have obtuse angles with respect to the directions of signal and power transmission.

### CROSS-REFERENCE TO RELATED APPLICATION

This application claims to benefit of Korean Patent Application No. 2003-96784, filed Dec. 24, 2003, in the Korean Intellectual Property Office, the disclosure of which is incorporated herein by reference.

### BACKGROUND OF THE INVENTION

1. Field of the Invention

The present invention relates, in general, to a printed circuit board and package having vias and, more particularly, to a printed circuit board and package having oblique vias that are obliquely formed with respect to the surfaces of circuit layers in the printed circuit board and the package so as to minimize high frequency loss.

2. Description of the Related Art

A via refers to the connection path of electric signals between layers in a multi-layered Printed Circuit Board (PCB) and a package, and is basically used to connect circuits formed on top and bottom surfaces in a two-sided PCB. Generally, such a via is formed in such a way that a hole is formed and the inner wall of the hole is plated to connect the top and bottom surfaces of a PCB through the hole.

The hole had previously been formed using a mechanical drill, but has recently been formed using a laser drill.

Such vias may be classified into the following types: a Plated Through Hole (PTH) type via that completely penetrates and connects overall layers, an Interstitial Via Hole (IVH) type via that penetrates and connects inner layers, and a buried via or blind via that is blocked at a portion thereof.

Additionally, there are a micro via having a diameter smaller than 100 um, a copper filled via having a via hole filled with copper, and a stacked via having vias perpendicularly stacked one on top of another.

The structures of vias used in conventional Integrated Circuit (IC) packages or PCBs are perpendicular to the surfaces of circuit layers regardless of the types of vias.

Accordingly, the path of power or a signal is formed of the combination of conductive wires and one or more vias bent at right angles several times to transmit the power or signal from one point to another in a PCB or an IC package.

FIG. 1 is a view showing a flip-chip bonding package 120 for high performance products, such as a Central Processing Unit (CPU) or graphic chip set, mounted on a PCB motherboard 100 according to the prior art.

Referring to FIG. 1, power and ground wires are included in a PCB motherboard 100, the substrate of a flip-chip bonding package 120 is connected to the PCB motherboard 100 through ball bonding 110, and a chip 140 is mounted on the substrate of the flip-chip bonding package 120 through solder bump bonding 130.

FIG. 1 further includes micro vias 160, a staggered via 170 having a stepped path for the flow of power or a signal, and a stacked via 180 having a plurality of micro vias stacked one on top of another.

As understood from FIG. 1, to transmit power or a signal from the chip 140 to the PCB motherboard 100, the path of the power or signal is formed of the combination of conductive wires and vias bent at right angles several times.

The reason why the path of the power or signal is formed of the combination of the conductive wires and the vias bent at right angles several times to transmit the power or signal from the chip 140 to the PCB motherboard 100 is mainly in that the conventional via structure is perpendicular to signal lines regardless of the types of vias.

Accordingly, the path of the power or signal is formed of the combination of the conductive wires and the vias bent at right angles several times to transmit the power or signal from the chip 140 to the PCB motherboard 100, so that high frequency loss generated by the high speed of digital signals is produced.

The high frequency loss is a loss (for example: insertion loss) generated when a high frequency passes through a circuit or device. The loss increases as the working frequency of an electronic device becomes higher, which deteriorates the transmission characteristics of a signal.

Accordingly, to appropriately transmit power or a signal at a high frequency in an IC package or a PCB, it is essential to maximally reduce high frequency loss. For example, a CPU currently used is operated in frequency bands ranging from 2 to 3 GHz. However, in the future, the operating frequency of the CPU will increase to 10 to 20 GHz or more to effectively perform the function thereof.

When the operating frequency increases, the conventional via structure limits the range of the working frequencies of the IC package or PCB due to the high frequency loss.

Furthermore, in the future, electronic products using the high frequency will increase, and a need for reducing the high frequency loss in the vias will increase also.

In the drawings, FIGS. 2a and 3a show conventional via structures, and FIG. 4a shows the distribution of an electric field in the conventional via structure.

Furthermore, FIG. 5 shows the loss values of the conventional via in frequency bands ranging from 0 to 10 GHz using Scattering parameters (S-parameters); FIG. 5 shows that, as the magnitude (db) of the S-parameters decreases in log scale, high frequency loss is reduced.

### SUMMARY OF THE INVENTION

Accordingly, the present invention has been made keeping in mind the above problems occurring in the conventional art, and an object of the present invention is to provide a via structure, which minimizes high frequency loss.

In order to accomplish the above object, the present invention provides a PCB or an IC package including an insulation layer, a plurality of circuit layers, and one or more vias obliquely formed with respect to the circuit layers and constructed to have obtuse angles with respect to the directions of signal and power transmission.

In addition, the present invention provides a PCB or an IC package including one or more vias obliquely formed to have obtuse angles with respect to the directions of signal and power transmission.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a view showing a flip-chip bonding package for high performance products, such as a CPU or graphic chip set, mounted on a motherboard according to the conventional art;

FIG. 2a is a view showing a conventional via structure;

FIG. 2b is a view showing an oblique via structure according to the present invention;

FIG. 3a is a view showing a conventional stacked via structure;

FIG. 3b is a view showing a stacked via structure according to the present invention;

FIG. 4a is a view showing the distribution of an electric field in a portion of a PCB or package including the conventional oblique via;

FIG. 4b is a view showing the distribution of an electric field in a portion of a PCB or package including the oblique via according to an embodiment of the present;

FIG. 5 is a view showing S-parameters according to frequencies in a portion of a PCB or package including the oblique via of the present invention;

FIG. 6 is a cross-section showing a PCB or package including the oblique via of the present invention;

FIG. 7a is a view showing a flip-chip bonding package for high performance products, such as the CPU or graphic chip set, mounted on a PCB motherboard including an oblique staggered via according to an embodiment of the present invention;

FIG. 7b is a view showing a flip-chip bonding package for high performance products, such as a CPU or graphic chip set, mounted on the PCB mother board including an oblique via according to another embodiment of the present invention; and

FIG. 7c is a view showing a flip-chip bonding package for high performance products, such as a CPU or graphic chip set, mounted on a PCB motherboard including an oblique stacked via according to still another embodiment of the present invention.

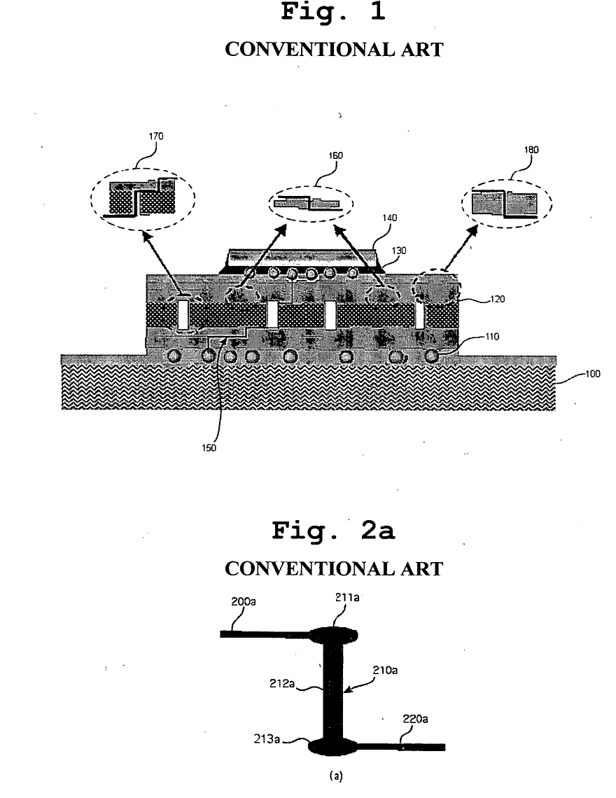

### DESCRIPTION OF THE PREFERRED EMBODIMENTS

Reference now should be made to the drawings, in which the same reference numerals are used throughout the different drawings to designate the same or similar components.

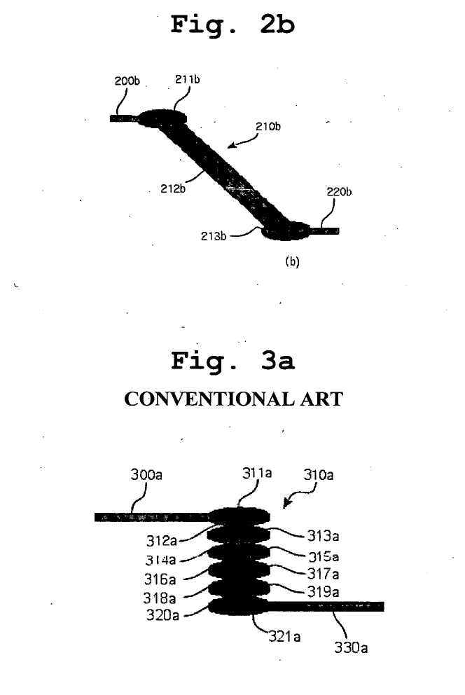

The embodiments of the present invention are described in detail with reference to FIGS. 2a to 7c below.

FIGS. 2a to 2b are views showing the structures of vias 210a and 210b, respectively, which connect signal lines 200a and 200b formed on the upper surface of a PCB to signal lines 220a and 220b formed on the lower surface of the PCB, respectively.

FIG. 2a shows a conventional via structure perpendicularly connected to the signal lines 200a and 220a. The conventional via structure is the primary cause of high frequency loss as described in the description of the related art.

That is, the sudden bending of the transmission path of a signal and power causes electromagnetic noise in a portion where the sudden bending occurs and hinders the transmission of a signal and power. In particular, the above-described problem becomes more serious as a frequency becomes higher. In this point of view, FIG. 2b shows an improved via structure according to the present invention.

In the improved via structure according to the present invention, the via is obliquely formed to allow the flow of a high frequency to be smoothly performed, so that high frequency loss is reduced compared to the conventional via structure.

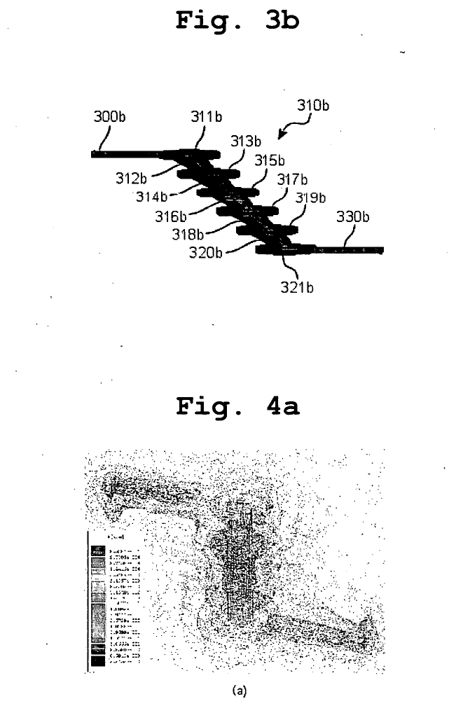

FIGS. 3a to 3b show via structures in stacked multi-layered PCBs.

FIG. 3a shows a stacked via structure in a conventional multi-layered PCB, in which a via is perpendicularly formed in a single layered PCB, and then a plurality of vias are arranged and stacked one on top of another to connect a signal line 300a formed on the upper surface of a PCB to a signal line 330a formed on the lower surface of the PCB.

In particular, in the via structure shown in FIG. 3a, the vias are perpendicularly formed in the plurality of layers and are connected to each other in a zigzag manner. This structure has a limitation not being able to reduce high frequency loss because the vias are perpendicularly formed in the layers.

FIG. 3b is a view showing a multilayered conductive via structure formed on a plurality of layers to connect a signal line 300b formed on the upper surface of a PCB to a signal line 330b formed on the lower surface of the PCB.

In the via structure shown in FIG. 3b, since oblique vias, other than perpendicular vias, are basically formed and stacked one on top of another, the via structure is effective in reducing high frequency loss.

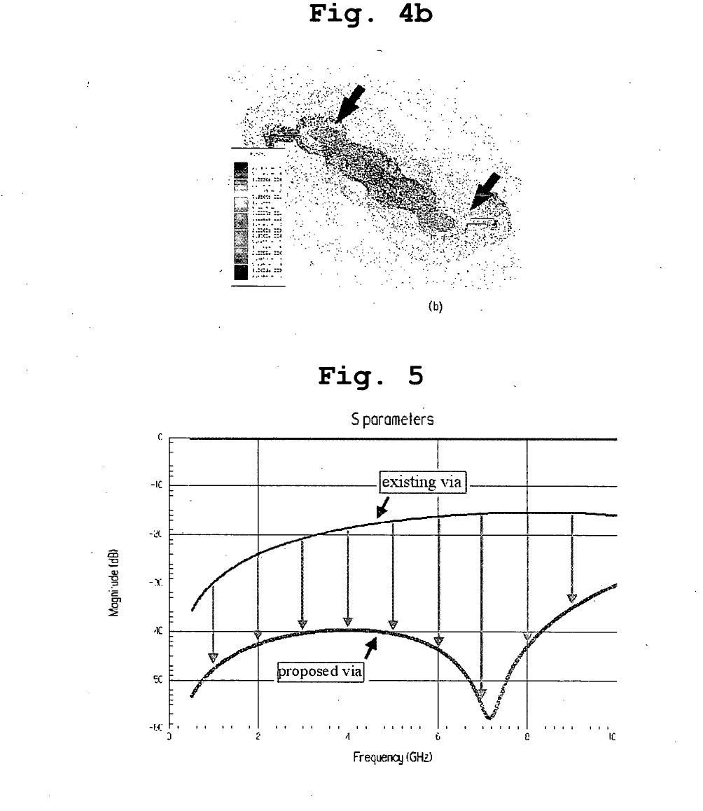

FIGS. 4a to 4b are views showing the distribution of electric fields.

FIG. 4a shows the distribution of the electric field in a conventional perpendicular via structure. FIG. 4b shows the distribution of the electric field in an oblique via structure of the present invention.

Referring to the drawings, the magnitude of the electric field is reduced in the oblique via structure provided in the present invention compared to the conventional via structure, and the dispersion of the electric field is reduced in the portions represented by arrows.

FIG. 5 is a graph showing S-parameters according to frequencies to confirm the reduction of high frequency loss.

Frequency bands ranging from 0 to 10 GHz are plotted along the X-axis, and the values of the S-parameters are plotted along the Y-axis in log scale. The via structure of the present invention can reduce high frequency loss compared to the conventional via structure in frequency bands ranging from 0 to 10 GHz by an average of more than 20 db.

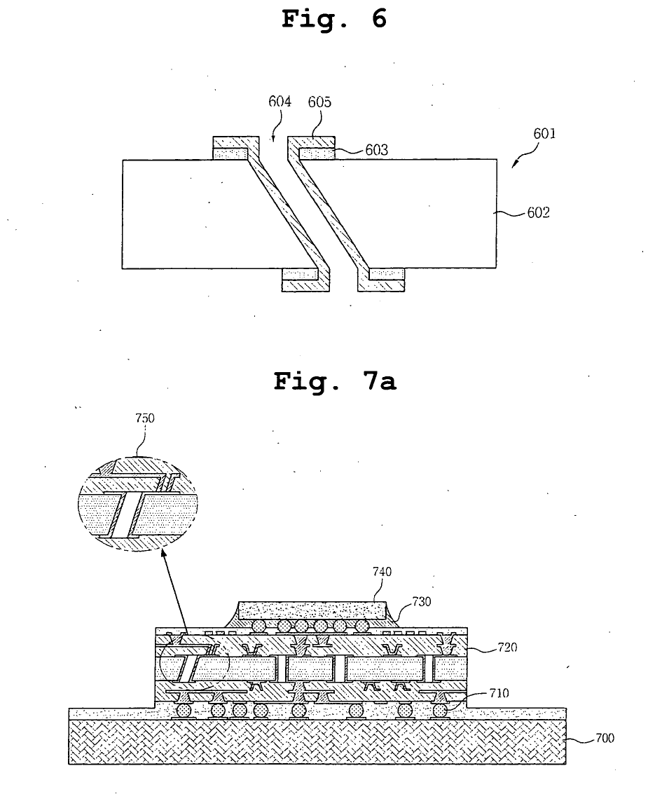

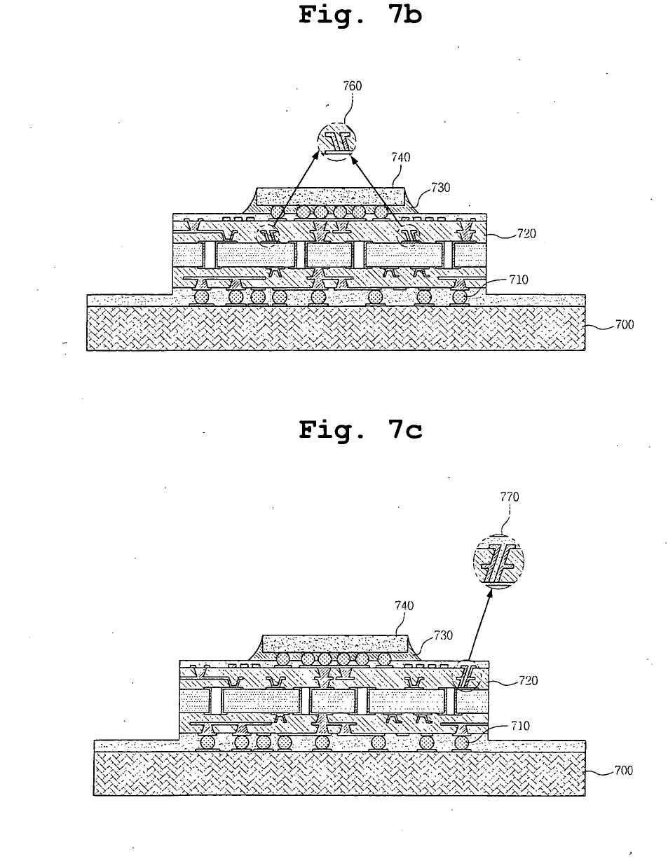

FIGS. 6 to 7c show examples in which oblique vias are applied to PCBs.

Referring to FIG. 6, the PCB includes the oblique via 604 obliquely formed in a Copper Clad Laminate (CCL) 601, and a copper plated layer 605 is formed on the oblique via 604 to provide conductivity.

FIG. 7a is a view showing a flip-chip bonding package for high performance products, such as a CPU or graphic chip set, mounted on a PCB motherboard including an oblique staggered via according to an embodiment of the present invention. FIG. 7b is a view showing a flip-chip bonding package for high performance products, such as a CPU or graphic chip set, mounted on a PCB motherboard including oblique micro vias according to another embodiment of the present invention. FIG. 7c is a view showing a flip-chip bonding package for high performance products, such as a CPU or graphic chip set, mounted on a PCB motherboard including an oblique stacked via according to still another embodiment of the present invention.

In FIG. 7a, the staggered via 750 is obliquely formed to have obtuse angles with respect to the flow of power or a signal so as to prevent high frequency loss.

The staggered via 750 allows the power or signal to flow along an oblique path when the power or signal flows from a chip 740 to the PCB motherboard 700, so that high frequency loss is prevented when the high frequency is applied.

In FIG. 7b, the micro via 760 is obliquely formed to have obtuse angles with respect to the flow of the power or signal so as to prevent high frequency loss.

In FIG. 7c, the stacked via 770 is obliquely formed to have obtuse angles with respect to the flow of the power or signal so as to prevent high frequency loss.

Meanwhile, in the case where a PCB is manufactured in a general way, the patterns of circuits are performed on a copper plate, thus forming the inner and outer layers of the PCB. However, recently, optical waveguides are inserted into a PCB to receive and transmit signals in the form of light using a polymer and a glass fiber. The PCB is referred to as an Electro-Optical Circuit Board (EOCB).

The via of the present invention can be applied both to a general via and to an optical via used in the EOCB.

Additionally, current mobile communication terminals must be miniaturized and lightened both to support high-speed, high-capacity communications and to be conveniently carried.

Accordingly, components used in the mobile communication terminals has been developed so as to implement extreme miniaturization and complex functions, and related components has rapidly been developed so as to implement a Multi-Chip Module (MCM) for mounting a plurality of bare chips on a Low Temperature Co-fired Ceramic (LTCC) in correspondence with the development of the mobile communication terminals.

The LTCC is manufactured by forming a substrate using a method of co-firing ceramics and metals at a low temperature of about 800 to 1000° C. The substrate is formed in such a way that glass and ceramics having a low melting point are mixed to form a green sheet having an appropriate dielectric constant, a conductive paste is printed on the green sheet and green sheets printed with conductive pastes are stacked one on top of another. The oblique via structure of the present invention can be used in the substrate using the LTCC.

As described above, the oblique via structure can be used in the substrate having the conventional perpendicular via structure as well as the PCB to reduce high frequency loss.

The present invention is effective in overcoming signal hindrance at a high frequency, which is generated due to the high speed of digital signals.

Furthermore, the present invention is effective in reducing high frequency loss generated in the vias of an IC package or a PCB that adopts a via structure, thus improving the performance of signal transmission in high frequency bands.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A Printed Circuit Board (PCB) comprising:
an insulation layer;
a plurality of circuit layers; and
one or more vias obliquely formed with respect to the circuit layers and constructed to have obtuse angles with respect to directions of signal and power transmission.

2. An Integrated Circuit (IC) package comprising:
an insulation layer;
a plurality of circuit layers; and
one or more vias obliquely formed with respect to the circuit layers and constructed to have obtuse angles with respect to directions of signal and power transmission.

3. A PCB, comprising:
one or more vias obliquely formed to have obtuse angles with respect to directions of signal and power transmission.

4. An IC package, comprising:
one or more vias obliquely formed to have obtuse angles with respect to directions of signal and power transmission.
